(19) United States
(12) Patent Application Publication
(10) Pub. No.: US 2025/0070733 A1
(43) Pub. Date: Feb. 27, 2025

(54) RF PUSH-PULL POWER AMPLIFIER CHIP AND RF FRONT-END MODULE

(71) Applicant: RADROCK (SHENZHEN) TECHNOLOGY CO., LTD., Shenzhen, Guangdong (CN)

(72) Inventors: Yuan Cao, Shenzhen, Guangdong (CN); Jianxing Ni, Shenzhen, Guangdong (CN)

(21) Appl. No.: 18/688,329

(22) PCT Filed: Nov. 9, 2022
(86) PCT No.: PCT/CN2022/130766

§ 371 Date: Feb. 29, 2024

(30) Foreign Application Priority Data
Sep. 30, 2021 (CN) 202111161780.4

(51) Int. Cl. H03F 3/26; H01L 23/66; H03F 1/56; H03F 3/24; H03F 3/45

(52) U.S. Cl. CPC H03F 3/26; H01L 23/66; H03F 1/565; H03F 3/245; H03F 3/4508; H01L 2223/6611; H01L 2223/6655; H03F 2200/06; H03F 2200/451

(57) ABSTRACT

The application discloses an RF push-pull power amplifier chip, wherein the second end of the first capacitor is connected to the first pad of the chip, and the second end of the second capacitor is connected to the second pad of the chip, and the first pad is bonded to the second pad by a wire. The first capacitor, second capacitor and wire form an impedance matching circuit, which participates in impedance matching of the chip together with the first balun. In this way, the RF push-pull power amplifier chip can support a larger bandwidth, and the equivalent inductance can be changed by adjusting the length of the wire, so that the impedance matching circuit can be adjusted more flexibly in a limited chip area. Therefore, the bandwidth performance of the RF push-pull power amplifier chip would not be affected, and the occupied area of the chip can be reduced.

The present application claims the benefit of Chinese Patent Application No. 202111161780.4, titled “RF push-pull power amplifier chip and RF front-end module”, filed on 30 Sep. 2021.

### TECHNICAL FIELD

The application relates to the technical field of radio frequency (RF), in particular to an RF push-pull power amplifier chip and an RF front-end module.

### BACKGROUND

With the maturity of short-distance and low-power wireless data transmission technology, wireless network technology is increasingly applied to new fields. Compared with wired communication, wireless communication plays an important role in modern communication field because of its advantages such as no need to lay open wires and convenient use. At present, in order to meet the performance index of impedance matching, the power amplifier using wireless network technology tends to cause deterioration of bandwidth performance of the power amplifier circuit. Therefore, how to ensure the bandwidth performance of power amplifiers while achieving impedance matching has become an urgent problem.

### SUMMARY

The embodiments of the application provide an RF push-pull power amplifier chip and an RF front-end module, aiming at solving the problem of poor bandwidth performance of power amplifiers.

An RF push-pull power amplifier chip is provided, including a first differential amplifier transistor, a second differential amplifier transistor, a first balun, a first capacitor and a second capacitor;

an output end of the first differential amplifier transistor is coupled to a first end of a primary coil of the first balun, and an output end of the second differential amplifier transistor is coupled to a second end of the primary coil of the first balun; and

a first end of the first capacitor is connected between the output end of the first differential amplifier transistor and the first end of the primary coil of the first balun, and a second end of the first capacitor is connected to a first pad of the push-pull power amplifier chip; a first end of the second capacitor is connected between the output end of the second differential amplifier transistor and the second end of the primary coil of the first balun, and a second end of the second capacitor is connected to a second pad of the push-pull power amplifier chip; and the first pad is bonded to the second pad by a wire.

Further, the RF push-pull power amplifier chip is configured to support amplification of high-frequency signals, and the high-frequency band is 5.1 Ghz-7.2 Ghz.

Further, the first balun includes a primary coil and a secondary coil; the primary coil includes a first primary coil segment and a second primary coil segment connected with each other, and the secondary coil includes a first secondary coil segment and a second secondary coil segment connected with each other.

Further, the first primary coil segment and the first secondary coil segment are coupled to form a first coupling coil, and the first coupling coil is located at a first metal layer of the RF push-pull power amplifier chip; and the second primary coil segment and the second secondary coil segment are coupled to form a second coupling coil, and the second coupling coil is located at a second metal layer of the RF push-pull power amplifier chip.

Further, a turns ratio of the primary coil and the secondary coil is 1:1.

Further, the RF push-pull power amplifier chip also includes a third capacitor, one end of the third capacitor is coupled between the first primary coil segment and the second primary coil segment, and another end is grounded.

Further, the RF push-pull power amplifier chip also includes a fourth capacitor and a fifth capacitor; the fourth capacitor is connected in series between the output end of the first differential amplifier transistor and the first end of the primary coil of the first balun, and the fifth capacitor is connected in series between the output end of the second differential amplifier transistor and the second end of the primary coil of the first balun.

Further, the RF push-pull power amplifier chip also includes a first matching network and a second matching network; the first matching network includes a first inductor and a first LC resonance circuit, the first inductor is connected in series between the output end of the first differential amplifier transistor and the first end of the primary coil of the first balun; one end of the first LC resonance circuit is connected between the output end of the first differential amplifier transistor and the first end of the primary coil of the first balun, and another end is grounded; and

the second matching network includes a second inductor and a second LC resonance circuit, the second inductor is connected in series between the output end of the second differential amplifier transistor and the second end of the primary coil of the first balun; one end of the second LC resonance circuit is connected between the output end of the second differential amplifier transistor and the second end of the primary coil of the first balun, and another end is grounded.

Further, the RF push-pull power amplifier chip further includes an eighth capacitor, the eighth capacitor is connected in series between the output end of the first differential amplifier transistor and the output end of the second differential amplifier transistor.

Further, the first LC resonance circuit and/or the second LC resonance circuit are configured to resonate at a second harmonic frequency point.

Further, the first differential amplifier transistor is a BJT and has a base, a collector and an emitter; the base of the first differential amplifier transistor receives a first RF input signal, the collector of the first differential amplifier transistor is coupled to the first end of the primary coil of the first balun via the first matching network, and the emitter of the first differential amplifier transistor is grounded; and

the second differential amplifier transistor is a BJT and has a base, a collector and an emitter, the base of the second differential amplifier transistor receives a second RF input signal, the collector of the second differential amplifier transistor is coupled to the second end of the primary coil of the first balun via the second matching network, and the emitter of the second differential amplifier transistor is grounded.

Further, a first end of the secondary coil of the first balun outputs an amplified first RF output signal, and a second end of the secondary coil outputs an amplified second RF output signal; or, the first end of the secondary coil of the first balun outputs an amplified RF output signal, and the second end of the secondary coil is grounded.

An RF push-pull power amplifier chip is provided, including a first differential amplifier transistor, a second differential amplifier transistor, a first balun, a sixth capacitor and a seventh capacitor; an output end of the first differential amplifier transistor is connected to a third pad of the push-pull power amplifier chip, and the third pad is bonded to a fourth pad of the push-pull power amplifier chip by a wire; an output end of the second differential amplifier transistor is connected to a fifth pad of the push-pull power amplifier chip, and the fifth pad is bonded to a sixth pad by a wire; the fourth pad is coupled to a first end of a primary coil of the first balun, and the sixth pad is coupled to a second end of the primary coil of the first balun; and

a first end of the sixth capacitor is connected to the third pad of the push-pull power amplifier chip, a second end of the sixth capacitor is configured to be connected to ground; a first end of the seventh capacitor is connected to the fifth pad of the push-pull power amplifier chip, and a second end of the seventh capacitor is configured to be connected to ground.

Further, the RF push-pull power amplifier chip further includes a first capacitor and a second capacitor; a first end of the first capacitor is connected to the fourth pad of the RF push-pull power amplifier chip, and a second end of the first capacitor is connected to a first pad of the push-pull power amplifier chip; a first end of the second capacitor is connected to the sixth pad of the RF push-pull power amplifier chip, and a second end of the second capacitor is connected to a second pad of the push-pull power amplifier chip; and the first pad is bonded to the second pad by a wire.

A RF front-end module is provided, including the RF push-pull power amplifier chip described above.

Further, the RF front-end module further includes a substrate and a feedback power end arranged on the substrate; the RF push-pull power amplifier chip is arranged on the substrate; the output end of the first differential amplifier transistor is connected to the third pad of the push-pull power amplifier chip, and the third pad is bonded to the feedback power end by a wire; and the output end of the second differential amplifier transistor is connected to the fourth pad of the push-pull power amplifier chip, and the fourth pad is bonded to the feedback power end by a wire.

Further, the RF front-end module further includes a decoupling capacitor, and one end of the decoupling capacitor is connected to the feedback power end, and another end is grounded.

The application provides an RF push-pull power amplifier chip, including a first differential amplifier transistor, a second differential amplifier transistor, a first balun, a first capacitor and a second capacitor; an output end of the first differential amplifier transistor is coupled to a first end of a primary coil of the first balun, and an output end of the second differential amplifier transistor is coupled to a second end of the primary coil of the first balun; and a first end of the first capacitor is connected between the output end of the first differential amplifier transistor and the first end of the primary coil of the first balun, and a second end of the first capacitor is connected to a first pad of the push-pull power amplifier chip; a first end of the second capacitor is connected between the output end of the second differential amplifier transistor and the second end of the primary coil of the first balun, and a second end of the second capacitor is connected to a second pad of the push-pull power amplifier chip; and the first pad is bonded to the second pad by a wire. The present application adopts a power amplifier with a push-pull architecture. The first capacitor is connected to the first end of the primary coil of the first balun of the push-pull power amplifier chip, the second capacitor is connected to the second end of the primary coil of the first balun, and the electrical connection between the first capacitor and the second capacitor is realized by wire bonding. Specifically, the first pad is bonded to the second pad by connecting the second end of the first capacitor to the first pad of the push-pull power amplifier chip and connecting the second end of the second capacitor to the second pad of the push-pull power amplifier chip. The first capacitor, second capacitor and the wire constitute an impedance matching circuit, which participates in the impedance matching of the RF push-pull power amplifier chip together with the first balun. In this way, the RF push-pull power amplifier chip is able to change with frequency, the impedance changes less, and the harmonic impedance converges more, thus achieving better harmonic suppression performance in a wider frequency band. And because the first capacitor and second capacitor of the application are connected by wire bonding, the equivalent inductance value can be changed by adjusting the length of the wire, so that the impedance matching circuit can be adjusted more flexibly in a limited chip area, thereby solving the problem that the chip area is too small to set an adjustable capacitor or adjustable inductor. Therefore, the bandwidth performance of the RF push-pull power amplifier chip would not be affected, and the occupied area of the RF push-pull power amplifier chip can be reduced.

The application provides an RF push-pull power amplifier chip, including a first differential amplifier transistor, a second differential amplifier transistor, a first balun, a sixth capacitor and a seventh capacitor; an output end of the first differential amplifier transistor is connected to a third pad of the push-pull power amplifier chip, and the third pad is bonded to a fourth pad of the push-pull power amplifier chip by a wire; an output end of the second differential amplifier transistor is connected to a fifth pad of the push-pull power amplifier chip, and the fifth pad is bonded to a sixth pad by a wire; the fourth pad is coupled to a first end of a primary coil of the first balun, and the sixth pad is coupled to a second end of the primary coil of the first balun; and a first end of the sixth capacitor is connected to the third pad of the push-pull power amplifier chip, the third pad is bonded to ground by a wire, a second end of the seventh capacitor is connected to the fifth pad of the push-pull power amplifier chip, and the fifth pad is bonded to ground by a wire. In the application, a power amplifier with a push-pull architecture is adopted. And in the RF push-pull power amplifier chip, the equivalent inductance of wire and sixth capacitor are used to form the first LC resonance circuit, the equivalent inductance of wire and seventh capacitor are used to form the second LC resonance circuit, the equivalence of wire and first LC resonance circuit are used to form a first matching network, and the equivalence of wire and second LC resonance circuit are used to form a second matching network. Through the above arrangements, the first matching network, second matching network and first balun participate together in the impedance conversion of the RF push-pull power amplifier chip. In this way, it not only solves the problem of increasing transmission loss caused by wires in the process of RF signal transmission, but also realizes impedance matching of RF push-pull power amplifier chip, thus solving the problem of poor bandwidth performance of RF push-pull power amplifier chip. Moreover, the equivalent inductance value can be adjusted by adjusting the length of the wire, so as to achieve the purpose of adjusting the resonance frequency points of the first LC resonance circuit and second LC resonance circuit. In this way, the RF push-pull power amplifier chip is able to change with frequency, the impedance changes less, and the harmonic impedance converges more, thus achieving better harmonic suppression performance in a wider frequency band, and further enabling the RF push-pull power amplifier chip to support a larger bandwidth.

### BRIEF DESCRIPTION OF THE DRAWINGS

In order to explain the technical solution of the embodiments of this application more clearly, the drawings described in the description of the embodiments of this application will be briefly introduced below. Obviously, the drawings in the present application and their accompanying detailed description are directed to merely exemplary embodiments of the application. F or those of ordinary skill in this field, other drawings may be obtained according to these drawings without any creative effort.

FIG. 1 is a schematic circuit diagram of an RF push-pull power amplifier chip according to an embodiment of the present application.

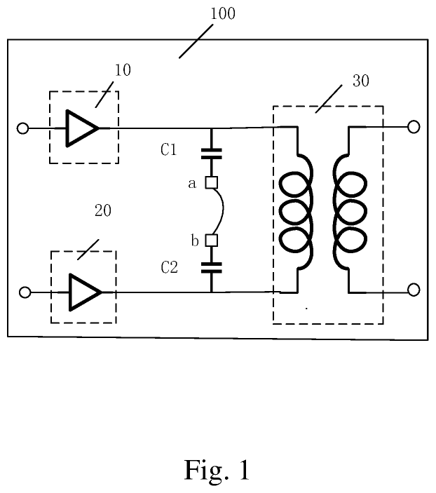

FIG. 2 is another schematic circuit diagram of an RF push-pull power amplifier chip according to an embodiment of the present application.

FIG. 3 is another schematic circuit diagram of an RF push-pull power amplifier chip according to an embodiment of the present application.

FIG. 4 is another schematic circuit diagram of an RF push-pull power amplifier chip according to an embodiment of the present application.

FIG. 5 is another schematic circuit diagram of an RF push-pull power amplifier chip according to an embodiment of the present application.

FIG. 6 is another schematic circuit diagram of an RF push-pull power amplifier chip according to an embodiment of the present application.

FIG. 7 is another schematic circuit diagram of an RF push-pull power amplifier chip according to an embodiment of the present application.

FIG. 8 is another schematic circuit diagram of an RF push-pull power amplifier chip according to an embodiment of the present application.

FIG. 9 is another schematic circuit diagram of an RF push-pull power amplifier chip according to an embodiment of the present application.

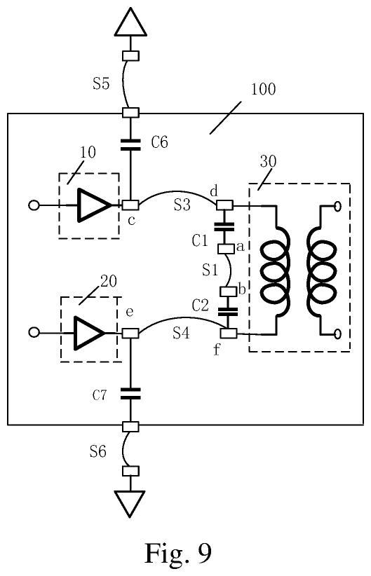

FIG. 10 is a schematic circuit diagram of an RF front-end module according to an embodiment of the present application.

Reference signs in the figures are as follows.

10. First differential amplifier transistor; 20. Second differential amplifier transistor; 30. First balun; 40. First matching circuit; 50. Second matching circuit; 401. First LC resonance circuit; 501. Second LC resonance circuit; L1. First inductor; L2. Second inductor; C1. First capacitor; C2. Second capacitor; C3. Third capacitor; C4. Fourth capacitor; C5. Fifth capacitor; C6. Sixth capacitor; C7. Seventh capacitor; C11. Eighth capacitor; C12. Decoupling capacitor; L6. Sixth inductor; L7. Seventh inductor; 100. RF push-pull power amplifier chip; 200. Substrate; a. First pad; b. Second pad; c. Third pad; d. Fourth pad; e. Fifth pad; f. Sixth pad.

### DETAILED DESCRIPTION OF PREFERRED EMBODIMENTS

The technical solutions in the embodiments of the present application will be clearly and completely described below with reference to the drawings in the embodiments of this application. Obviously, the described embodiments are part of the embodiments of this application, but not all of them. Based on the embodiments in this application, all other embodiments obtained by those of ordinary skill in the art without creative effort belong to the protection scope of this application.

It should be understood that the exemplary embodiments may be embodied in many different forms and should not be construed as being limited to the exemplary embodiments set forth herein. Rather, these embodiments are provided so that this disclosure will be thorough and complete, and will fully convey the protection scope of this application to those skilled in the art. In the drawings, like reference signs refer to like elements throughout, and the size and relative sizes of layers and regions may be exaggerated for clarity.

It should be understood that when an element or layer is referred to as being “on”, “adjacent to”, “connected with” or “coupled to” other elements or layers, it may be directly on, adjacent to, connected with or coupled to other elements or layers, or intervening elements or layers. Rather, when an element is referred to as being “directly on”, “directly adjacent to”, “directly connected with” or “directly coupled to” other elements or layers, there is no intervening element or layer. It should be understood that although the terms first, second, third, etc. are used to describe various elements, components, areas, layers and/or parts, these elements, components, areas, layers and/or parts should not be limited by these terms. These terms are only used to distinguish one element, part, area, layer or part from another element, part, area, layer or part. Therefore, without departing from the teachings of this application, the first element, part, area, layer or part discussed below may be represented as the second element, part, area, layer or part.

Spatial terms such as “below”, “under”, “above” and “on” may be used here for convenience of description to describe the relationship between one element or feature and other elements or features shown in the figures. It should be understood that in addition to the orientations shown in the figures, the spatial relationship terms are intended to include different orientations of devices in use and operation. For example, if the device in the figures is turned upside down, then the elements or features described as “below” or “under” other elements or features would be “above” or “on” other elements or features. Therefore, the exemplary terms “below” or “under” may include the orientations of “above” or “on”. The device may be otherwise oriented (rotated by 90 degrees or other orientations) and the spatial description terms used here are interpreted accordingly.

The terms used here are only for the purpose of describing specific embodiments and not as a limitation of the present application. As used herein, singular forms of “a”, “an” and “the/said” are also intended to include plural forms, unless the context clearly indicates otherwise. It should also be understood that the terms “comprise” and/or “include” used in this specification specify the presence of said features, integers, steps, operations, elements and/or components, but do not exclude the presence or addition of one or more other features, integers, steps, operations, elements, components and/or groups. As used herein, the term “and/or” includes any and all combinations of related listed items.

For a thorough understanding of this application, detailed structures and steps will be set forth in the following description, so as to illustrate the technical solution proposed in the present application. The preferred embodiments of the present application are described in detail as follows, but besides these detailed descriptions, the present application may also have other embodiments.

This embodiment provides an RF push-pull power amplifier chip 100, which includes a first differential amplifier transistor 10, a second differential amplifier transistor 20, a first balun 30, a first capacitor C1 and a second capacitor C2.

In this embodiment, an RF push-pull power amplifier chip is a chip for amplifying signals in a frequency band corresponding to a wireless technology network communication standard, i.e., the RF push-pull power amplifier chip can support wireless network technology. Preferably, the RF push-pull power amplifier chip may amplify signals in the frequency band corresponding to WIFI. For example, the RF push-pull power amplifier chip can amplify signals in the frequency band corresponding to WIFI6/6E.

It should be noted that the RF push-pull power amplifier chip in this embodiment is a bare chip that has not been packaged. That is, all components included in the RF push-pull power amplifier chip, such as the first differential amplifier transistor, second differential amplifier transistor, first balun, first capacitor and second capacitor, are integrated on a same bare chip.

The output end of the first differential amplifier transistor 10 is coupled to the first end of the primary coil of the first balun 30, and the output end of the second differential amplifier transistor 20 is coupled to the second end of the primary coil of the first balun 30.

The first differential amplifier transistor 10 and the second differential amplifier transistor 20 may be bipolar junction transistors (BJT) or field effect transistors (FET). Optionally, the first differential amplifier transistor 10 includes at least one BJT (e.g., HBT) or at least one field effect transistor. As an example, the first differential amplifier transistor 10 may be a plurality of BJTs connected in parallel. The second differential amplifier transistor 20 includes at least one BJT (for example, HBT) or at least one field effect transistor. As an example, the second differential amplifier transistor 20 may be a plurality of BJTs connected in parallel.

In a specific embodiment, the first differential amplifier transistor 10 is configured to amplify a first RF input signal and output a first RF amplified signal, and the first RF amplified signal is coupled to the first end of the primary coil of the first balun 30. The second differential amplifier transistor 20 is configured to amplify a second RF input signal and output a second RF amplified signal, and the second RF amplified signal is coupled to the second end of the primary coil of the first balun 30. And, the first RF input signal may be the RF signal amplified by the corresponding pre-stage amplifier circuit, or may be one of the balanced RF signals obtained by converting the unbalanced input RF signals. Similarly, the second RF input signal may be the RF signal amplified by the corresponding pre-stage amplifier circuit, or may be one of the balanced RF signals obtained by converting the unbalanced input RF signals.

It can be understood that the first differential amplifier transistor 10 and the second differential amplifier transistor 20 are any amplifier stage in the RF push-pull power amplifier chip. The amplifier stage may be any amplifier stage in the driving stage, intermediate stage or output stage.

In a specific embodiment, the RF push-pull power amplifier chip further includes a pre-stage conversion circuit (not shown), for example, the pre-stage conversion circuit may be a pre-stage conversion balun. The pre-stage conversion balun is used to convert the unbalanced RF input signal into a balanced first RF input signal and a balanced second RF input signal. And it is used to input the first RF input signal to the input end of the first differential amplifier transistor 10, and input the second RF input signal to the input end of the second differential amplifier transistor 20.

The first end of the first capacitor C1 is connected between the output end of the first differential amplifier transistor 10 and the first end of the primary coil of the first balun 30, and the second end is connected to the first pad a of the push-pull power amplifier chip 100. The first end of the second capacitor C2 is connected to the output end of the second differential amplifier transistor 20 and the second end of the primary coil of the first balun 30, and the second end is connected to the second pad b of the push-pull power amplifier chip 100, and the first pad a is bonded to the second pad b by a wire.

In a specific embodiment, in order to realize impedance matching at the output of the RF push-pull power amplifier chip 100 and relieve the pressure of impedance conversion by using the first balun 30 alone, so that the RF push-pull power amplifier chip 100 can support a larger bandwidth. Generally, impedance matching circuit is connected among the first differential amplifier transistor 10, second differential amplifier transistor 20 and first balun 30, and impedance matching is achieved by adjusting the capacitance and/or inductance values in the impedance matching circuit.

In this embodiment, the power amplifier circuit with push-pull architecture is adopted, and the first capacitor C1 is connected between the output end of the first differential amplifier transistor 10 and the first end of the primary coil of the first balun 30. And, the second capacitor C2 is connected between the output end of the second differential amplifier transistor 20 and the second end of the primary coil of the first balun 30, and the first capacitor C1 and the second capacitor C2 are electrically connected by wire bonding. Specifically, the RF push-pull power amplifier chip 100 is provided with the first pad a and second pad b, and the second end of the first capacitor C1 is connected to the first pad a of the push-pull power amplifier chip 100. The second end of the second capacitor C2 is connected to the second pad b of the push-pull power amplifier chip 100, and the first pad a is bonded to the second pad b by a wire S1. And, the first pad a may be bonded to the second pad b by one or more wires. The first capacitor C1, second capacitor C2 and the wire S1 constitute an impedance matching circuit, which participates in the impedance matching of the RF push-pull power amplifier chip together with the first balun 30. In this way, the RF push-pull power amplifier chip is enabled to support a larger bandwidth, and thus solving the problem of poor bandwidth performance of power amplifier. And because the first capacitor C1 and second capacitor C2 of the application are connected by wire bonding, the equivalent inductance value can be changed by adjusting the length of the wire S1, so that the impedance matching circuit can be adjusted more flexibly in a limited chip area, thereby solving the problem that the chip area is too small to set an adjustable capacitor or adjustable inductor. Therefore, the bandwidth performance of the RF push-pull power amplifier chip would not be affected, and the occupied area of the RF push-pull power amplifier chip can be reduced.

In a specific embodiment, the RF push-pull power amplifier chip can amplify signals in the frequency band corresponding to WIFI6/6E, wherein the high-frequency band is 5.1 Ghz-7.2 Ghz.

Preferably, in this embodiment, the RF push-pull power amplifier chip can amplify signals in the frequency band corresponding to WIFI6/6E, and the communication standard of WIFI6/6E can support the amplification of high-frequency signals, so the RF push-pull power amplifier chip can support the amplification of high-frequency signals. And, the high-frequency band is preferably 5.1 Ghz-7.2 Ghz.

In this embodiment, the RF push-pull power amplifier chip is configured to support the amplification of high-frequency signals, and the high-frequency band is 5.1 Ghz-7.2 Ghz. Thus, the problem of poor bandwidth performance of the power amplifier with 6G wireless network technology (Wi-Fi6) is solved.

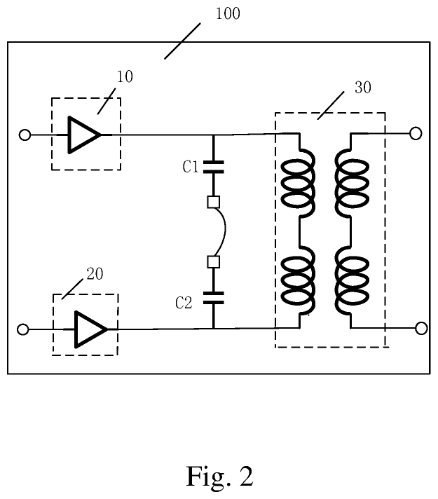

Referring to FIG. 2 below, the first balun includes a primary coil and a secondary coil; and the primary coil includes a first primary coil segment and a second primary coil segment which are connected with each other, and the secondary coil includes a first secondary coil segment and a second secondary coil segment which are connected with each other.

In this embodiment, the first primary coil segment and the second primary coil segment of the primary coil of the first balun 30 are separately arranged, and the first secondary coil segment and the second secondary coil segment of the secondary coil are separately arranged.

Further, the first primary coil segment and the first secondary coil segment are coupled to each other on a first metal layer, and the second primary coil segment and the second secondary coil segment are coupled to each other on a second metal layer. The first primary coil segment and the second primary coil segment distributed in different metal layers can be connected by jumper wires or binding wires. The second primary coil segment and the second secondary coil segment distributed in different metal layers can be connected by jumper wires or binding wires. The first primary coil segment and the first secondary coil segment are coupled to form a first coupling coil, and the first coupling coil is located at the first metal layer of the RF push-pull power amplifier chip. the second primary coil segment and the second secondary coil segment are coupled to form a second coupling coil, and the second coupling coil is located at a second metal layer of the RF push-pull power amplifier chip.

The RF push-pull power amplifier chip includes at least two metal layers, and the first primary coil segment and the first secondary coil segment are coupled to form a first coupling coil, and the first coupling coil is located at the first metal layer of the RF push-pull power amplifier chip. the second primary coil segment and the second secondary coil segment are coupled to form a second coupling coil, and the second coupling coil is located at a second metal layer of the RF push-pull power amplifier chip. The first coupling coil and the second coupling coil form a double coupling coil and are respectively located in two adjacent metal layers. In a specific embodiment, due to the limited area of the chip, the first coupling coil and the second coupling coil formed by the first balun are respectively arranged in two adjacent metal layers, so that the coupling degree of the primary coil and the secondary coil of the first balun can be ensured, and the occupied area of the first balun on the chip can be further reduced, which is beneficial to the integrated design of the RF push-pull power amplifier chip.

And, the turns ratio of the primary coil and the secondary coil is 1:1.

Specifically, the impedance matching circuit composed of the first capacitor C1, the second capacitor C2 and the wire S1 participates in the impedance matching of the RF push-pull power amplifier chip together with the first balun 30. Therefore, the first balun 30 of the present application can realize impedance conversion with fewer coil turns, thereby reducing the output loss of the RF push-pull power amplifier chip 100. In addition, because the number of turns of the first balun coil for impedance conversion is reduced, the layout design of the first balun can be realized on the chip, which reduces the design cost and makes the design of the first balun more flexible.

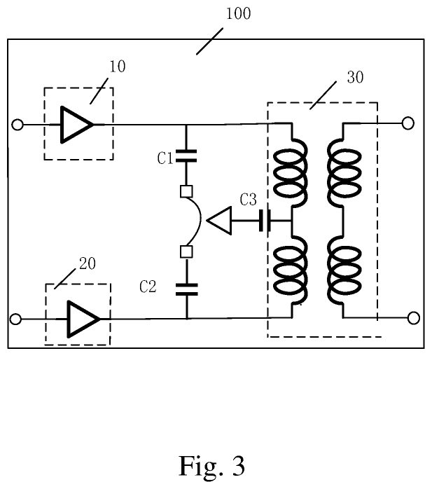

In a specific embodiment, as shown in FIG. 3 below, it further includes a third capacitor C3, one end of the third capacitor C3 is coupled between the first primary coil segment and the second primary coil segment, and the other end is grounded.

In this embodiment, one end of the third capacitor C3 is coupled between the first primary coil segment and the second primary coil segment, and the other end is grounded. In this way, while ensuring the bandwidth performance of the RF push-pull power amplifier chip, the suppression degree of even harmonics in the RF push-pull power amplifier chip can be further improved, so that the even harmonics suppression performance is better in a wider frequency band.

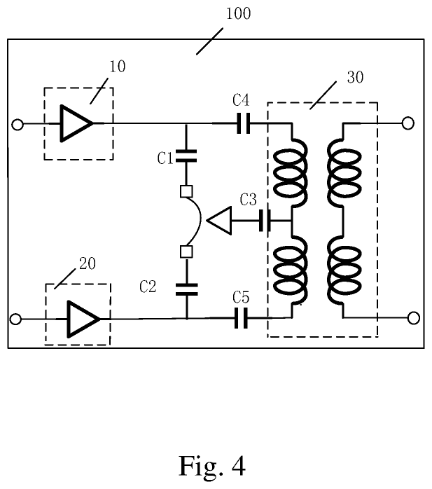

Referring to FIG. 4 below, the RF push-pull power amplifier chip 100 further includes a fourth capacitor C4 and a fifth capacitor C5; the fourth capacitor C4 is connected in series between the output end of the first differential amplifier transistor 10 and the first end of the primary coil of the first balun 30, and the fifth capacitor C5 is connected in series between the output end of the second differential amplifier transistor 20 and the second end of the primary coil of the first balun 30.

It should be noted that if other components or other circuits are arranged between the output end of the first differential amplifier transistor 10 and the first end of the primary coil of the first balun 30, the fourth capacitor C4 is arranged adjacent to the first end of the primary coil of the first balun 30. Similarly, if other components or other circuits are arranged between the output end of the second differential amplifier transistor 20 and the second end of the primary coil of the first balun 30, the fifth capacitor C5 is arranged adjacent to the second end of the primary coil of the first balun 30. In this way, it can participate in the impedance matching of RF push-pull power amplifier chip together with first balun 30.

In this embodiment, the fourth capacitor C4 and the fifth capacitor C5 can not only block the DC signal in the RF signal output by the output end of the first differential amplifier transistor 10 and the output end of the second differential amplifier transistor 20, but also participate in the impedance matching of RF push-pull power amplifier chip with the first balun 30, so as to further optimize the bandwidth performance of RF push-pull power amplifier chip.

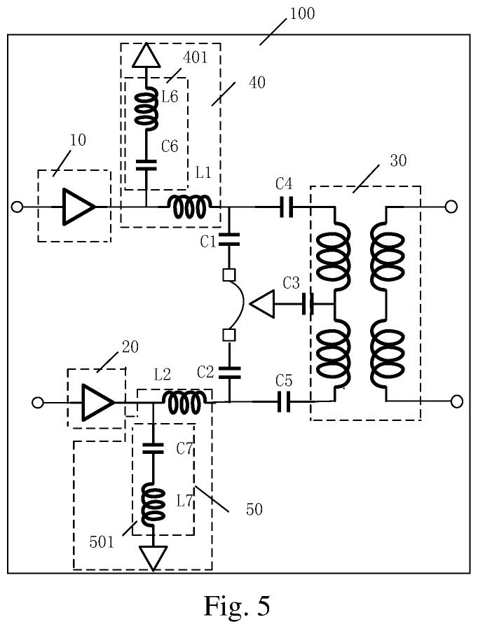

Referring to FIG. 5, the RF push-pull power amplifier chip further includes a first matching network 40 and a second matching network 50. the first matching network 40 includes a first inductor L1 and a first LC resonance circuit 401, the first inductor L1 is connected in series between the output end of the first differential amplifier transistor 10 and the first end of the primary coil of the first balun 30; one end of the first LC resonance circuit 401 is connected between the output end of the first differential amplifier transistor 10 and the first end of the primary coil of the first balun 30, and another end is grounded; and the second matching network 50 includes a second inductor L2 and a second LC resonance circuit 501, the second inductor L2 is connected in series between the output end of the second differential amplifier transistor 20 and the second end of the primary coil of the first balun 30; one end of the second LC resonance circuit 501 is connected between the output end of the second differential amplifier transistor 20 and the second end of the primary coil of the first balun 30, and another end is grounded.

Specifically, the output end of the first differential amplifier transistor 10 is coupled to the first end of the primary coil of the first balun 30 via the first matching network 40; the output end 50 of the second differential amplifier transistor 20 is coupled to the second end of the primary coil of the first balun 30 via the second matching network 50.

Specifically, the first matching network includes a first inductor L1 and a first LC resonance circuit 401, and the first inductor L1 is connected in series between the output end of the first differential amplifier transistor 10 and the first end of the primary coil of the first balun 30. As an example, one end of the first inductor L1 is connected to the output end of the first differential amplifier transistor 10, and the other end is connected to the first end of the primary coil of the first balun 30. One end of the first LC resonance circuit 401 is connected between the output end of the first differential amplifier transistor 10 and the first end of the primary coil of the first balun 30, and the other end is grounded. The first LC resonance circuit 401 is a resonance circuit composed of a sixth capacitor C6 and a sixth inductor L6 in series. Optionally, one end of the first LC resonance circuit 401 is connected between the output end of the first differential amplifier transistor 10 and the first inductor L1, and the other end is grounded. Alternatively, one end of the first LC resonance circuit 401 is connected between the first inductor L1 and the first end of the primary coil of the first balun 30, and the other end is grounded.

The second matching network includes a second inductor L2 and a second LC resonance circuit 501; the second inductor L2 is connected in series between the output end of the second differential amplifier transistor 20 and the second end of the primary coil of the first balun 30. For example, one end of the second inductor L2 is connected to the output end of the second differential amplifier transistor 20, and the other end is connected to the second end of the primary coil of the first balun 30. One end of the second LC resonance circuit 50 is connected between the output end of the second differential amplifier transistor 20 and the second end of the primary coil of the first balun 30, and the other end is grounded. And, the second LC resonance circuit 501 is a resonance circuit composed of a seventh capacitor C7 and a seventh inductor L7 connected in series. Optionally, one end of the second LC resonance circuit 501 is connected between the output end of the second differential amplifier transistor 20 and the second inductor L2, and the other end is grounded. Alternatively, one end of the second LC resonance circuit 501 is connected between the second inductor L2 and the second end of the primary coil of the first balun 30, and the other end is grounded.

It should be noted that in this embodiment, the specific positions of the fourth capacitor C4 and the first inductor L1 connected in series between the output end of the first differential amplifier transistor 10 and the first end of the primary coil of the first balun 30, and the specific positions of the fifth capacitor C5 and the second inductor L2 connected in series between the output end of the second differential amplifier transistor 20 and the second end of the primary coil of the first balun 30 are not specifically limited. That is, the output of the first differential amplifier transistor 10 may be connected to the fourth capacitor C4 and then to the first inductor L1, or it may be connected to the first inductor L1 and then to the fourth capacitor C4. Similarly, the output of the second differential amplifier transistor 20 may be connected to the fifth capacitor C5 and then to the second inductor L2, or it may be connected to the second inductor L2 and then to the fifth capacitor C5. The above can be customized according to actual situation.

In this embodiment, the first inductor L1 is connected between the output end of the first differential amplifier transistor 10 and the first end of the primary coil of the first balun 30; one end of the first LC resonance circuit 401 is connected between the output end of the first differential amplifier transistor 10 and the first end of the primary coil of the first balun 30, and the other end is grounded; the second inductor L2 is connected between the output end of the second differential amplifier transmitter 10 and the second end of the primary coil of the first balun 30; and one end of the second LC resonance circuit 501 is connected between the output end of the second differential amplifier transistor 20 and the second end of the primary coil of the first balun 30, and the other end is grounded. Through the above arrangements, the first matching network 40 composed of the first inductor L1 and the first LC resonance circuit 401 and the second matching network 50 composed of the second inductor L2 and the second LC resonance circuit 501 participate in the impedance conversion of the RF push-pull power amplifier chip together with the first balun 30 to realize impedance matching. In this way, not only the fundamental wave performance of the push-pull power amplifier circuit can be improved, but also the resonant frequency points of the first LC resonance circuit 401 and the second LC resonance circuit 501 can be adjusted, so that the RF push-pull power amplifier chip is able to change with frequency, the impedance changes less, and the harmonic impedance converges more, thus achieving better harmonic suppression performance in a wider frequency band, and further enabling the RF push-pull power amplifier chip to support a larger bandwidth.

As an example, if the first LC resonance circuit and the second LC resonance circuit are configured to resonate at a second harmonic frequency point, the RF push-pull power amplifier chip in this embodiment realizes impedance matching under the joint action of “the first matching network 40 composed of the first inductor L1 and the first LC resonance circuit 401”, “the second matching network 50 composed of the second inductor L2 and the second LC resonance circuit 501” and the first balun 30. Therefore, not only the fundamental wave performance of the push-pull power amplifier circuit can be improved, but also the RF push-pull power amplifier chip can change with frequency, and its impedance change is smaller, and the second harmonic impedance is more convergent, thus achieving better harmonic suppression performance in a wider frequency band.

As another example, if the first LC resonance circuit and the second LC resonance circuit are configured to resonate at a trip harmonic frequency point, the RF push-pull power amplifier chip in this embodiment realizes impedance matching under the joint action of “the first matching network 40 composed of the first inductor L1 and the first LC resonance circuit 401”, “the second matching network 50 composed of the second inductor L2 and the second LC resonance circuit 501” and the first balun 30. Therefore, not only the fundamental wave performance of the push-pull power amplifier circuit can be improved, but also the third-order impedance of the RF push-pull power amplifier chip can be further improved, so that the RF push-pull power amplifier chip can have better harmonic suppression in a wider frequency band.

It should be noted that this embodiment can further improve the bandwidth performance of the RF push-pull power amplifier chip by adjusting the resonance frequency points of the first LC resonance circuit 401 and the second LC resonance circuit 501, so that the RF push-pull power amplifier chip can support a larger bandwidth.

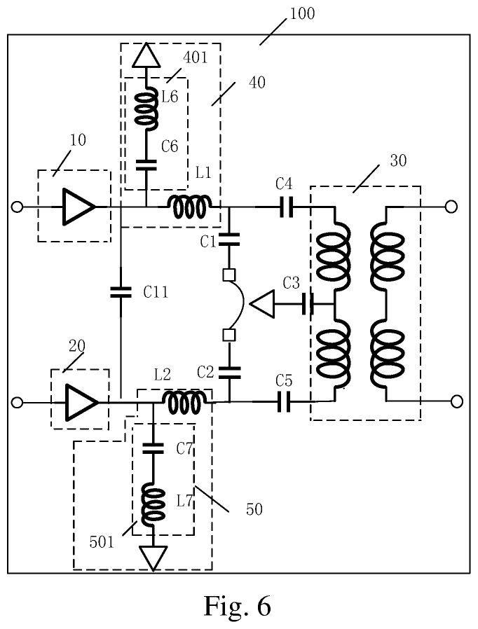

Referring to FIG. 6 below, in a specific embodiment, the RF push-pull power amplifier chip further includes an eighth capacitor C11, the eighth capacitor C11 is connected in series between the output end of the first differential amplifier transistor 10 and the output end of the second differential amplifier transistor 20. That is, one end of the eighth capacitor C11 is coupled to the output end of the first differential amplifier transistor 10, and the other end is coupled to the output end of the second differential amplifier transistor 200.

In a specific embodiment, when RF push-pull power amplifier chip works in a certain frequency band, the bandwidth performance of push-pull power amplifier circuit may not be ideal when “the first matching network 40 composed of the first inductor L1 and the first LC resonance circuit 401”, “the second matching network 50 composed of the second inductor L2 and the second LC resonance circuit 501” and the first balun 30 participate in impedance matching of RF push-pull power amplifier chip. In view of this, in this application, an eighth capacitor C1 is connected in series between the output end of the first differential amplifier transistor 10 and the output end of the second differential amplifier transistor 20. In this case, the eighth capacitor C11, first matching network 10 and second matching network 20 participate in the impedance matching of the RF push-pull power amplifier chip together with the first balun 30. Therefore, the bandwidth performance of the fundamental impedance of the RF push-pull power amplifier chip would not be affected, and meanwhile, the RF push-pull power amplifier chip can change with frequency, and its impedance change is small, and the second harmonic impedance is more convergent, so that the harmonic suppression performance is better in a wider frequency band.

In another specific embodiment, the eighth capacitor C11 may be equivalent to a first matching capacitor and a second matching capacitor. Specifically, one end of the first matching capacitor is connected to the output end of the first differential amplifier transistor 10, the other end is connected to ground, and one end of the second matching capacitor is connected to the output end of the second differential amplifier transistor 20, and the other end is connected to ground. The first matching capacitor, second matching capacitor, first matching network 10 and second matching network 20 participate in the impedance matching of the RF push-pull power amplifier chip together with the first balun 30. Therefore, the bandwidth performance of the fundamental impedance of the RF push-pull power amplifier chip would not be affected, and meanwhile, the harmonic impedance of the RF push-pull power amplifier chip can be further optimized, so that the RF push-pull power amplifier chip changes with frequency, the impedance change is small, and the second harmonic impedance is more convergent, thus achieving better harmonic suppression performance in a wider frequency band.

In a specific embodiment, one end of the first LC resonance circuit is connected to the output end of the first differential amplifier transistor, and one end of the second LC resonance circuit is connected to the output end of the second differential amplifier transistor. Or, one end of the first LC resonance circuit is connected to the first end of the primary coil of the first balun, and one end of the second LC resonance circuit is connected to the second end of the primary coil of the first balun.

In a specific embodiment, the first LC resonance circuit 401 and the second LC resonance circuit 501 are configured to resonate at a second harmonic frequency point.

In a specific embodiment, “the first matching network 40 composed of the first inductor L1 and the first LC resonance circuit 401”, “the second matching network 50 composed of the second inductor L2 and the second LC resonance circuit 501” and the first balun 30 participate in impedance conversion of RF push-pull power amplifier chip together with the first balun 30 to realize impedance matching. Therefore, the performance of the fundamental wave of the RF push-pull power amplifier chip is guaranteed, and the RF push-pull power amplifier chip changes with frequency, the impedance change is smaller, and the second harmonic impedance is more convergent, so that the harmonic suppression performance is better in a wider frequency band.

In a specific embodiment, one end of the first LC resonance circuit is connected between the output end of the first differential amplifier transistor and the first inductor; one end of the second LC resonance circuit is connected between the output end of the second differential amplifier transistor and the second inductor. Or, one end of the first LC resonance circuit is connected to the first inductor and the first end of the primary coils of the first balun, and one end of the second LC resonance circuit is connected to the second inductor and the second end of the primary coils of the first balun.

One end of the first LC resonance circuit 401 is connected between the output end of the first differential amplifier transistor 10 and the first inductor L1; one end of the second LC resonance circuit 501 is connected between the output end of the second differential amplifier transistor and the second inductor L2.

One end of the first LC resonance circuit 401 is connected between the first inductor L1 and the first end of the primary coil of the first balun 30, and one end of the second LC resonance circuit 501 is connected between the second inductor L2 and the second end of the primary coil of the first balun 30. It should be noted that if other components are provided between the first inductor L1 and the first end of the primary coil of the first balun 30, one end of the first LC resonance circuit 401 is preferably connected to one end of the first inductor L1. If other components are arranged between the second inductor L2 and the second end of the primary coil of the first balun 30, one end of the second LC resonance circuit 401 is preferably connected to one end of the second inductor L2.

In a specific embodiment, since the impedance of the output end of the first differential amplifier transistor 10 and the impedance of the output end of the second differential amplifier transistor are small, one end of the first LC resonance circuit 401 is connected between the output end of the first differential amplifier transistor 10 and the first inductor L1, and the other end is connected to ground; and one end of the second LC resonance circuit 501 is connected between the output end of the second differential amplifier transistor and the second inductor L2, and the other end is connected to ground. In this way, the second harmonic of RF push-pull power amplifier chip can be better suppressed, so that the RF push-pull power amplifier chip changes with frequency, the impedance change is small, and the second harmonic impedance is more convergent, thus achieving better harmonic suppression performance in a wider frequency band.

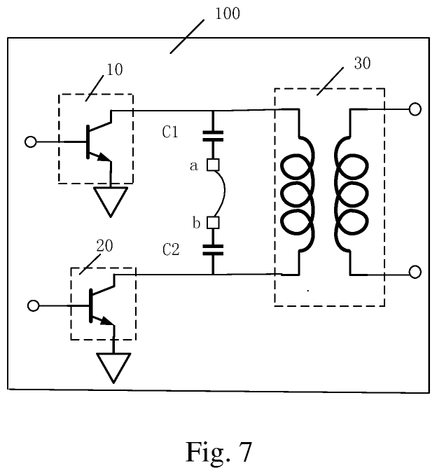

In a specific embodiment, as shown in FIG. 7 below, the first differential amplifier transistor 10 is a BJT and has a base, a collector and an emitter; the base of the first differential amplifier transistor 10 receives a first RF input signal, the collector of the first differential amplifier transistor is coupled to the first end of the primary coil segment, and the emitter of the first differential amplifier transistor 10 is grounded.

Specifically, the first RF input signal is input to the base of the first differential amplifier transistor 10, and after being amplified by the first differential amplifier transistor 10, the first RF amplified signal is output from the collector of the first differential amplifier transistor 10 to the first end of the first coil segment.

The second differential amplifier transistor 20 is a BJT and has a base, a collector and an emitter, the base of the second differential amplifier transistor 20 receives a second RF input signal, the collector of the second differential amplifier transistor 20 is coupled to the second end of the primary coil segment, and the emitter of the second differential amplifier transistor is grounded.

Specifically, the second RF input signal is input to the base of the second differential amplifier transistor 20, and after being amplified by the second differential amplifier transistor 20, the second RF amplified signal is output from the collector of the second differential amplifier transistor 20 to the second end of the second coil segment.

Further, after receiving the first RF amplified signal and the second RF amplified signal, the first balun 30 performs conversion processing on the first RF amplified signal and the second RF amplified signal, and inputs the converted first RF amplified signal and the converted second RF amplified signal to a post-stage circuit.

In a specific embodiment, the first end of the secondary coil of the first balun 30 outputs an amplified first RF output signal, and the second end of the secondary coil outputs an amplified second RF output signal. Alternatively, the first end of the secondary coil of the first balun 30 outputs an amplified RF output signal, and the second end of the secondary coil is grounded.

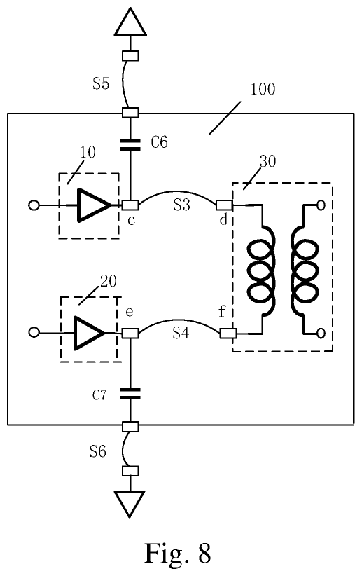

Referring to FIG. 8 below, the application provides another RF push-pull power amplifier chip 100, which includes a first differential amplifier transistor 10, a second differential amplifier transistor 20, a first balun 30, a sixth capacitor C6 and a seventh capacitor C7.

An output end of the first differential amplifier transistor 10 is connected to a third pad c of the push-pull power amplifier chip 100, and the third pad c is bonded to a fourth pad d of the push-pull power amplifier chip 100 by a wire; an output end of the second differential amplifier transistor 20 is connected to a fifth pad e of the push-pull power amplifier chip 100, and the fifth pad e is bonded to the sixth pad f by a wire; the fourth pad d is coupled to the first end of the primary coil of the first balun 30, and the sixth pad f is coupled to the second end of the primary coil of the first balun.

A first end of the sixth capacitor C6 is connected to the third pad c of the push-pull power amplifier chip 100, a second end of the sixth capacitor C7 is configured to be connected to ground, a first end of the seventh capacitor C7 is connected to the fifth pad e of the push-pull power amplifier chip 100, and a second end of the seventh capacitor C7 is configured to be connected to ground.

In a specific embodiment, since the impedance of the output end of the first differential amplifier transistor 10 and the impedance of the output end of the second differential amplifier transistor are small, the first end of the sixth capacitor C6 is connected to the third pad c of the RF push-pull power amplifier chip 200, and the second end of the sixth capacitor C6 is configured to be connected to ground. Preferably, the second end of the sixth capacitor C6 is bonded to ground by a wire. The second end of the sixth capacitor C6 can may bonded to ground through one or more wires. The first end of the seventh capacitor C7 is connected to the fifth pad e of the push-pull power amplifier chip 200, and the second end of the seventh capacitor C7 is configured to be connected to ground. Preferably, the second end of the seventh capacitor C7 is bonded to ground by a wire. The second end of the seventh capacitor may be bonded to ground through one or more wires. In this way, the second harmonic of RF push-pull power amplifier chip can be better suppressed, so that the RF push-pull power amplifier chip changes with frequency, the impedance change is small, and the second harmonic impedance is more convergent, thus achieving better harmonic suppression performance in a wider frequency band.

In a specific embodiment, in order to realize the electrical connection between the first differential amplifier transistor 10 and the second differential amplifier transistor 20 and the first balun 30, wire bonding can be adopted for the connection. Specifically, a third pad c, fourth pad d, fifth pad e and sixth pad f may be provided on the RF push-pull power amplifier chip 100. The output end of the first differential amplifier transistor 10 is connected to the third pad c of the RF push-pull power amplifier chip 100, the third pad c is bonded to the fourth pad d by a wire S3, and the fourth pad d is coupled to the first end of the primary coil of the first balun 30. And, the third pad c may be bonded to the fourth pad d through one or more wires. Moreover, the output end of the second differential amplifier transistor 20 is connected to the fifth pad e of the RF push-pull pow amplifier chip 100, the fifth pad e is bonded to the sixth pad f by a wire S4, and the sixth pad f is coupled to the second end of the primary coil of the first balun 30. And, the fifth pad c is bonded to the sixth pad f through one or more wires. Thereby realizing the electrical connection between the first differential amplifier transistor 10 and the second differential amplifier transistor 20 and the first balun 30.

Further, since the occupied area of the inductor on the RF push-pull power amplifier chip is often very large, in this application, the first end of the sixth capacitor C6 is connected to the third pad c of the RF push-pull power amplifier chip 200, the second end of the sixth capacitor C6 is bonded to ground by a wire, the first end of the seventh capacitor C7 is connected to the fifth pad c of the push-pull power amplifier chip 200, and the second end of the seventh capacitor C7 is bonded to ground by a wire. Specifically, the second end of the sixth capacitor C6 is bonded to ground through one or more wires S5, and the second end of the seventh capacitor C7 is bonded to ground through one or more wires S6. Optionally, the sixth capacitor C6 may be connected to the ground end arranged on the substrate by the wire S5, or may be connected to the ground end arranged on the chip by the wire S5. Similarly, the seventh capacitor C7 may be connected to the ground end arranged on the substrate by the wire S6, or may be connected to the ground end arranged on the chip by the wire S6. In this application, the equivalent inductance of the wire S5 and the sixth capacitor C6 constitute the first LC resonance circuit, and the equivalent inductance of the wire S6 and the seventh capacitor C7 constitute the second LC resonance circuit, thus reducing the area of the RF push-pull power amplifier chip.

In this embodiment, the push-pull power amplifier circuit is adopted. The equivalent inductance of wire S5 and sixth capacitor C6 constitute the first LC resonance circuit, the equivalent inductance of wire S6 and seventh capacitor C7 constitute the second LC resonance circuit, the equivalent inductance of wire S3 and the first LC resonance circuit constitute the first matching network, and the equivalent inductance of wire S4 and the second LC resonance circuit constitute the second matching network. Therefore, the first matching network, the second matching network and the first balun 30 participate in the impedance conversion of the RF push-pull power amplifier chip to realize impedance matching, thus solving the problem of poor bandwidth performance of the power amplifier. In this way, not only can the fundamental wave performance of the RF push-pull power amplifier chip be improved, but also the resonant frequency point of the first LC resonance circuit can be adjusted by adjusting the equivalent inductance value of the wire S5 or the capacitance value of the sixth capacitor C6, and the resonant frequency point of the second LC resonance circuit 501 can be adjusted by adjusting the equivalent inductance value of the wire S6 or the capacitance value of the seventh capacitor C7, so that the RF push-pull power amplifier chip changes with the frequency, the impedance change is small, and the second harmonic impedance is more convergent. Thereby realize better harmonic suppression performance in a wide frequency band range, enabling that RF push-pull power amplifier chip to support a lager bandwidth, and also solving the problem of increased transmission loss caused by wires in the process of transmitting RF signals.

In a specific embodiment, the RF push-pull power amplifier chip 100 further includes a first capacitor C1 and a second capacitor C2. The first end of the first capacitor C1 is connected to the fourth pad d of the RF push-pull power amplifier chip, and the second end is connected to the first pad a of the push-pull power amplifier chip. The first end of the second capacitor C2 is connected to the sixth pad f of the RF push-pull power amplifier chip 100, the second end is connected to the second pad b of the push-pull power amplifier chip, and the first pad a is bonded to the second pad b by a wire.

In this embodiment, the first end of the first capacitor C1 is connected to the fourth pad d of the RF push-pull power amplifier chip, and the second end is connected to the first pad a of the push-pull power amplifier chip; the first end of the second capacitor C2 is connected to the sixth pad f of the RF push-pull power amplifier chip 100, and the second end is connected to the second pad b of the push-pull power amplifier chip; and the first pad and the second pad b are connected by wire bonding. With the above arrangement, the electrical connection between the first capacitor C1 and the second capacitor C2 is realized. And, the first pad a may be bonded to the second pad b by one or more wires. The first capacitor C1, second capacitor C2 and the wire S1 constitute an impedance matching circuit, which participates in the impedance matching of the RF push-pull power amplifier chip together with the first balun 30. In this way, the RF push-pull power amplifier chip is enabled to support a larger bandwidth. And because the first capacitor C1 and second capacitor C2 of the application are connected by wire bonding, the equivalent inductance value can be changed by adjusting the length of the wire S1, so that the impedance matching circuit can be adjusted more flexibly in a limited chip area, thereby solving the problem that the chip area is too small to set an adjustable capacitor or adjustable inductor. Therefore, the bandwidth performance of the RF push-pull power amplifier chip would not be affected, and the occupied area of the RF push-pull power amplifier chip can be reduced.

The application further provides an RF front-end module, including the RF push-pull power amplifier chip of any of the above embodiments.

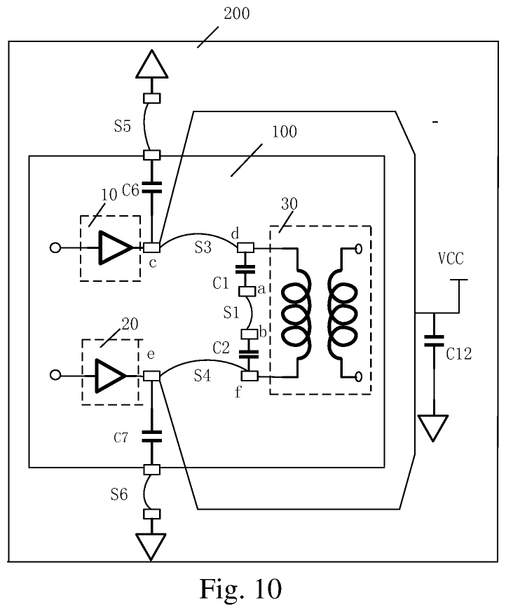

Referring to FIG. 10 below, the RF front-end module further includes a substrate 200 and a feedback power end VCC arranged on the substrate 200, the RF push-pull power amplifier chip 100 is arranged on the substrate 200.

The output end of the first differential amplifier transistor 10 is connected to the third pad c of the push-pull power amplifier chip, and the third pad c is bonded to the feedback power end VCC by a wire.

The output end of the second differential amplifier transistor 20 is connected to the fourth pad d of the push-pull power amplifier chip, and the fourth pad d is bonded to the feedback power end VCC by a wire.

And, the feedback power end VCC is a port connected with feedback power. The feedback signal provided by the feedback power is transmitted to the output end of the first differential amplifier transistor 10 and the output end of the second differential amplifier transistor 20 via the feedback power end VCC, so as to ensure that the first differential amplifier transistor 10 and the second differential amplifier transistor 20 can work regularly. In this embodiment, since the area of the RF push-pull power amplifier chip is limited, the feedback power end VCC is arranged on the substrate, and the feedback power end VCC is connected to the third pad c and the fourth pad d of the push-pull power amplifier chip 100 through wire bonding. The output end of the first differential amplifier transistor 10 is connected to the third pad c of the push-pull power amplifier chip 100, the output end of the second differential amplifier transistor 20 is connected to the fourth pad d of the push-pull power amplifier chip 100, so as to feed the first differential amplifier transistor 10 and the second differential amplifier transistor 20.

Further, it also includes a decoupling capacitor C12, one end of which is connected to the feedback power end VCC, and the other end is grounded.

Further, in order to further ensure the stability of the feedback signal provided by the feedback power end VCC to the first differential amplifier transistor 10 and the second differential amplifier transistor 20, a decoupling capacitor C12 is adopted in this application, one end of the decoupling capacitor C12 is connected to the feedback power end VCC, and the other end is grounded. In this application, the feed signal can be provided to the first differential amplifier transistor 10 and the second differential amplifier transistor 20 simply by using one feedback power end VCC. And by connecting the decoupling capacitor C12 to the feedback power end VCC, the stability of the feed signal provided to the first differential amplifier transistor 10 and the second differential amplifier transistor 20 can be ensured simply by using one decoupling capacitor C12. Thereby, the overall performance of the RF front-end module is guaranteed to be unchanged, and the occupied area of the RF front-end module is further reduced.

It should be noted that the decoupling capacitor C12 in this embodiment may be arranged on the substrate 200 or the RF push-pull power amplifier chip 100.

In one embodiment, the RF push-pull power amplifier chip may be a chip manufactured by processes such as GaAs, GaN or CMOS.

Understandably, for the wire bonding mode adopted in the embodiments of the present application, one or more wires may be used for the connection, the details are not repeated here.

The above embodiments are merely used to illustrate the technical solution of the present application, rather than limit it. Although the application has been described in detail with reference to the foregoing embodiments, it should be understood by those skilled in the art that it is still possible to modify the technical solutions described in the foregoing embodiments, or equivalently replace some technical features thereof. These modifications and equivalents do not make the nature of the corresponding technical solution deviates from the spirit and scope of the present application, and shall be included in the protection scope of the present application.

1. An RF push-pull power amplifier chip, comprising a first differential amplifier transistor, a second differential amplifier transistor, a first balun, a first capacitor and a second capacitor;
an output end of the first differential amplifier transistor is coupled to a first end of a primary coil of the first balun, and an output end of the second differential amplifier transistor is coupled to a second end of the primary coil of the first balun; and
a first end of the first capacitor is connected between the output end of the first differential amplifier transistor and the first end of the primary coil of the first balun, and a second end of the first capacitor is connected to a first pad of the push-pull power amplifier chip; a first end of the second capacitor is connected between the output end of the second differential amplifier transistor and the second end of the primary coil of the first balun, and a second end of the second capacitor is connected to a second pad of the push-pull power amplifier chip; and the first pad is bonded to the second pad by a wire.

2. The RF push-pull power amplifier chip of claim 1, wherein the RF push-pull power amplifier chip is configured to support amplification of high-frequency signals, and the high-frequency band is 5.1 Ghz-7.2 Ghz.

3. The RF push-pull power amplifier chip of claim 1, wherein the first balun comprises a primary coil and a secondary coil; the primary coil comprises a first primary coil segment and a second primary coil segment connected with each other, and the secondary coil comprises a first secondary coil segment and a second secondary coil segment connected with each other.

4. The RF push-pull power amplifier chip of claim 3, wherein the first primary coil segment and the first secondary coil segment are coupled to form a first coupling coil, and the first coupling coil is located at a first metal layer of the RF push-pull power amplifier chip; and
the second primary coil segment and the second secondary coil segment are coupled to form a second coupling coil, and the second coupling coil is located at a second metal layer of the RF push-pull power amplifier chip.

5. The RF push-pull power amplifier chip of claim 3, wherein a turns ratio of the primary coil and the secondary coil is 1:1.

6. The RF push-pull power amplifier chip of claim 3, further comprising a third capacitor, one end of the third capacitor is coupled between the first primary coil segment and the second primary coil segment, and another end is grounded.

7. The RF push-pull power amplifier chip of claim 1, further comprising a fourth capacitor and a fifth capacitor; the fourth capacitor is connected in series between the output end of the first differential amplifier transistor and the first end of the primary coil of the first balun, and the fifth capacitor is connected in series between the output end of the second differential amplifier transistor and the second end of the primary coil of the first balun.

8. The RF push-pull power amplifier chip of claim 7, further comprising a first matching network and a second matching network;
the first matching network comprises a first inductor and a first LC resonance circuit, the first inductor is connected in series between the output end of the first differential amplifier transistor and the first end of the primary coil of the first balun; one end of the first LC resonance circuit is connected between the output end of the first differential amplifier transistor and the first end of the primary coil of the first balun, and another end is grounded; and
the second matching network comprises a second inductor and a second LC resonance circuit, the second inductor is connected in series between the output end of the second differential amplifier transistor and the second end of the primary coil of the first balun; one end of the second LC resonance circuit is connected between the output end of the second differential amplifier transistor and the second end of the primary coil of the first balun, and another end is grounded.

9. The RF push-pull power amplifier chip of claim 8, further comprising an eighth capacitor, the eighth capacitor is connected in series between the output end of the first differential amplifier transistor and the output end of the second differential amplifier transistor.

10. The RF push-pull power amplifier chip of claim 8, wherein the first LC resonance circuit and the second LC resonance circuit are configured to resonate at a second harmonic frequency point.

11. The RF push-pull power amplifier chip of claim 8, wherein the first differential amplifier transistor is a BJT and has a base, a collector and an emitter; the base of the first differential amplifier transistor receives a first RF input signal, the collector of the first differential amplifier transistor is coupled to the first end of the primary coil of the first balun via the first matching network, and the emitter of the first differential amplifier transistor is grounded; and
the second differential amplifier transistor is a BJT and has a base, a collector and an emitter, the base of the second differential amplifier transistor receives a second RF input signal, the collector of the second differential amplifier transistor is coupled to the second end of the primary coil of the first balun via the second matching network, and the emitter of the second differential amplifier transistor is grounded.

12. The RF push-pull power amplifier chip of claim 1, wherein a first end of the secondary coil of the first balun outputs an amplified first RF output signal, and a second end of the secondary coil outputs an amplified second RF output signal; or, the first end of the secondary coil of the first balun outputs an amplified RF output signal, and the second end of the secondary coil is grounded.

13. An RF push-pull power amplifier chip, comprising a first differential amplifier transistor, a second differential amplifier transistor, a first balun, a sixth capacitor and a seventh capacitor;
an output end of the first differential amplifier transistor is connected to a third pad of the push-pull power amplifier chip, and the third pad is bonded to a fourth pad of the push-pull power amplifier chip by a wire; an output end of the second differential amplifier transistor is connected to a fifth pad of the push-pull power amplifier chip, and the fifth pad is bonded to a sixth pad by a wire; the fourth pad is coupled to a first end of a primary coil of the first balun, and the sixth pad is coupled to a second end of the primary coil of the first balun; and
a first end of the sixth capacitor is connected to the third pad of the push-pull power amplifier chip, a second end of the sixth capacitor is configured to be connected to ground; a first end of the seventh capacitor is connected to the fifth pad of the push-pull power amplifier chip, and a second end of the seventh capacitor is configured to be connected to ground.

14. The RF push-pull power amplifier chip of claim 13, further comprising a first capacitor and a second capacitor; a first end of the first capacitor is connected to the fourth pad of the RF push-pull power amplifier chip, and a second end of the first capacitor is connected to a first pad of the push-pull power amplifier chip; a first end of the second capacitor is connected to the sixth pad of the RF push-pull power amplifier chip, and a second end of the second capacitor is connected to a second pad of the push-pull power amplifier chip; and the first pad is bonded to the second pad by a wire.

15. A RF front-end module, comprising the RF push-pull power amplifier chip of claim 1.

16. The RF front-end module of claim 15, further comprising a substrate and a feedback power end arranged on the substrate; the RF push-pull power amplifier chip is arranged on the substrate;
the output end of the first differential amplifier transistor is connected to the third pad of the push-pull power amplifier chip, and the third pad is bonded to the feedback power end by a wire; and
the output end of the second differential amplifier transistor is connected to the fourth pad of the push-pull power amplifier chip, and the fourth pad is bonded to the feedback power end by a wire.

17. The RF front-end module of claim 16, further comprising a decoupling capacitor, wherein one end of the decoupling capacitor is connected to the feedback power end, and another end is grounded.
